(19) United States
(12) Patent Application Publication
(10) Pub. No.: US 2025/0138061 A1
(43) Pub. Date: May 1, 2025

(54) METHOD AND CIRCUIT FOR MONITORING VOLTAGE DROOP RESPONSE

(71) Applicant: Arm Limited, Cambridge (GB)

(72) Inventors: Amit Chhabra, Noida (IN); Rainer Herberholz, Great Abington (GB); Yimajian Yan, Santa Clara, CA (US); Sumant Srikant, Cambridge (GB)

(73) Assignee: Arm Limited, Cambridge (GB)

(21) Appl. No.: 18/925,495

(22) Filed: Oct. 24, 2024

(30) Foreign Application Priority Data
Oct. 27, 2023 (IN) 202311073298
Nov. 24, 2023 (IN) 202311079973
Mar. 20, 2024 (GB) 2403980.2
Mar. 20, 2024 (GB) 2403981.0

(51) Int. Cl. G01R 19/25; G01R 19/175

(52) U.S. Cl. CPC G01R 19/2503; G01R 19/175

(57) ABSTRACT

There is described a method of monitoring an electronic circuit voltage droop response; the method comprising: switching activity, in response to a voltage droop event, from a nominal clock source to a fallback clock source; and, optionally, switching activity, in response to a voltage recovery event, from a fallback clock source to a nominal clock source; wherein a voltage recovery event comprises a predetermined duration according to a configurable delay value without a voltage droop. The method further comprises at least one of: measuring a number of instances of switching from a nominal clock source to a fallback clock source; measuring an actual duration during which activity proceeds according to the fallback clock source without a voltage droop; measuring a fallback duration during which activity proceeds according to the fallback clock source; and measuring a number of instances of switching from a fallback clock source to a nominal clock source occurring during a voltage droop. Finally, the method may comprise modifying the switching to optimise activity efficiency based on the measuring. There is also described an electronic circuit configured to monitor voltage droop response of another electronic circuit according to the method.

### TECHNICAL FIELD

The present techniques relate to a method and circuit for monitoring a voltage droop response. In particular, the present techniques relate to monitoring a response to voltage droop events in an information processing system.

### BACKGROUND OF THE DISCLOSURE

Some computer circuits (e.g. a central processor unit (CPU) or graphics processor unit (GPU)) may experience performance issues. For example, a CPU can generate voltage droops due to large changes in current required from a power delivery network (PDN).

There is a need for mitigation action to address such performance issues.

### SUMMARY OF THE DISCLOSURE

The present techniques relate to monitoring, verifying or modifying mitigation of such performance issues or improving known mitigation techniques.

According to a first approach of present techniques, there is provided a method of monitoring an electronic circuit voltage droop response; the method comprising: switching activity, in response to a voltage droop event, from a nominal clock source to a fallback clock source; and measuring a number of instances of said switching.

By measuring the number of instances of switching from a nominal clock source to a fallback clock source, a number of mitigation events may be recorded. A mitigation event may be triggered by a voltage droop event occurring while activity proceeds according to the nominal clock source. Voltage droop events may take place during a mitigation event, for example, while activity proceeds according to the fallback clock source or during a transition between clock sources. Such voltage droop events may not constitute mitigation events. Accordingly, measuring an instance of switching from a nominal clock source to a fallback clock source may provide an accurate measure of mitigation events, as voltage droop events which trigger a response.

The method may further comprise switching activity, in response to a sign off violation event, from a nominal clock source to a zero source; and measuring a number of instances of said switching. Switching to a zero source may comprise pausing activity such that activity does not proceed according to any clock. Switching to a zero source may comprise stopping activity so that no further clock edges propagate once activity is switched to that source. Activity may be switched to a zero source in response to events other than a sign off-violation. For example, in response to a voltage droop event, activity may be switched from the nominal clock source to the zero source before being switched from the zero source to the fallback clock source.

By measuring the number of instances of switching from a nominal clock source to a zero source, a number of sign off mitigation events may be recorded. In addition, a number of instances of switching to the zero source from any clock source may be measured.

According to a further approach, there is provided an electronic circuit configured to monitor voltage droop response of another electronic circuit; the electronic circuit providing: a nominal clock source; a fallback clock source; and a mitigation count value; wherein, in response to a voltage droop event, the electronic circuit is switched from a nominal clock source to a fallback clock source; and wherein, in response to switching the electronic circuit from the nominal clock source to the fallback clock source, the mitigation count value is incremented. In some embodiments, the electronic circuit may comprise a telemetry circuit. In some embodiments, the electronic circuit may comprise a subject circuit upon which an impact of voltage droop is mitigated. In some embodiments, the electronic circuit configured to monitor voltage droop is a telemetry circuit and the electronic circuit switched between clock sources is a subject circuit. The electronic circuit being monitored may comprise a clock controlled state machine.

The electronic circuit may further provide a zero source and a sign off count value; wherein, in response to a sign off violation event, activity is switched from the nominal clock source to the zero source; and wherein, in response to switching activity from the nominal clock source to the zero source, the sign off count value is incremented.

Monitoring an electronic circuit according to any approach of the disclosure may comprise remote monitoring or telemetry. A user or a control system may use the measured values to verify operation or the circuit and/or modify the circuit to optimise performance and efficiency.

The mitigation count value may be stored in a register. Accordingly, the mitigation count value may be monitored, used in calculation or act as a trigger in further circuit verification and optimisation circuits.

According to a further approach, there is provided a method of monitoring an electronic circuit voltage droop response; the method comprising: switching activity, in response to a voltage droop event, from a nominal clock source to a fallback clock source; and switching activity, in response to a voltage recovery event, from a fallback clock source to a nominal clock source; wherein a voltage recovery event comprises a predetermined duration according to a configurable delay value without a voltage droop; and measuring an actual duration during which activity proceeds according to the fallback clock source without a voltage droop.

By measuring an actual duration during which activity proceeds according to the fallback clock source without a voltage droop, an actual time during which a voltage droop is not present during the mitigation event is measured. Once a voltage recovers so that a droop is not present, the voltage may be adequate for activity to proceed according to the nominal source. A transition to the nominal source is not initiated until the configurable delay value has elapsed without a voltage droop. By measuring actual duration, a fitness of the configurable delay value may be judged. For example, an actual duration that is many times longer than the configurable delay value may indicate that activity is proceeding according to the fallback clock source for a relatively long duration before switching to the nominal clock source. In this case, the configurable delay value may be reduced to allow a transition to the nominal clock source to take place sooner after a voltage droop event to increase a duration during which activity proceeds according to the nominal clock. In an alternate implementation, hysteresis techniques can be implemented to ensure that the output of the droop detector is stable after the droop has recovered.

An actual duration may be measured for each mitigation event. In other words, the value of actual duration may be reset between mitigation events so that an accurate actual duration during which activity proceeds according to the fallback clock source without a voltage droop for each mitigation event is measured. Before being reset, the value of actual duration may be recorded.

Alternatively, an actual duration may be measured during a predetermined time period, or over a number of mitigation events, for example, ten mitigation events, before being recorded and reset.

The method may further comprise calculating a delay loop value by dividing the actual duration by the configurable delay value. The delay loop value may recontextualise the actual duration into a multiplier of the configurable delay value. A minimum value of actual duration is identical to the configurable delay value. Accordingly, recording the actual duration in terms of the configurable delay value may provide meaningful insight into characteristics of the voltage droop response.

The method may further comprise plotting the delay loop value in a histogram. By plotting a histogram, a distribution of delay loop values may be visualised. In particular, where a delay loop value is obtained for each mitigation event, it may be possible to compare how actual duration compares with the configurable delay value over a large number of mitigation events. From the histogram, a user may verify the operation of the response and identify any modifications to the configurable delay value that may be appropriate.

The method may further comprise modifying the predetermined duration by reconfiguring the configurable delay value. Modifying the predetermined duration may modify the switching by adjusting the actual duration. Such modification may be based on the histogram. The configurable delay value may be reconfigured to improve efficiency and/or performance of the response, e.g., by increasing a duration during which activity proceeds according to the nominal clock source.

As well as the configurable delay value, other modifications may be made to improve an efficiency and/or performance of the response, or circuit. In particular, if a transition from nominal clock source to fallback clock source and back again is subject to a transition pause, this transition pause may be modified to optimise the response, or circuit. Further, a droop voltage threshold below which the PDN voltage triggers a voltage droop event may be adjusted. Furthermore, a sign off voltage threshold below which the PDN voltage triggers a sign off violation event may be adjusted. Recovery voltage thresholds above which the PDN voltage is considered recovered from a voltage droop or sign off violation event may also be adjusted. In this way, the voltage droop response may be tuned to offer optimal performance. In particular, optimal performance may be defined as operating according to the nominal clock source for as great a proportion of time as possible, while adequately mitigating negative effects of voltage droop to remain within thermal budget and extend battery life.

A faster response to a voltage droop event or a voltage recovery event may enable more aggressive, i.e., lower, thresholds to be used. For example, a lower droop voltage threshold and lower recovery voltage thresholds may be used with a faster response. For this reason, in some cases, it may be advantageous to reduce a transition pause and a configurable delay value.

According to a further approach, there is provided an electronic circuit configured to monitor voltage droop response of another electronic circuit; the electronic circuit providing: a nominal clock source; a fallback clock source; a configurable delay value and a mitigation duration value; wherein, in response to a voltage droop event, the electronic circuit is switched from the nominal clock source to the fallback clock source; and wherein, in response to a voltage recovery event, the electronic circuit is switched from the fallback clock source to a nominal clock source; wherein a voltage recovery event comprises a predetermined duration according to the configurable delay value without a voltage droop; and wherein a duration during which activity proceeds according to the fallback clock source without a voltage droop is recorded as the mitigation duration value.

The mitigation duration value may be stored in a register. Accordingly, the mitigation duration value may be monitored, used in calculation or act as a trigger in further circuit verification and optimisation circuits.

A delay loop value may be calculated by dividing the mitigation duration value by the configurable delay value. The delay loop value may be plotted in a histogram. Advantages of calculating the delay loop value and plotting the same in a histogram are discussed above.

The configurable delay value may be reconfigurable to modify the predetermined duration. Modifying the predetermined duration may modify switching by adjusting the mitigation duration value. Such modification may be based on the histogram. Adjusting the mitigation duration value may comprise reducing the mitigation duration value, for example reducing the mitigation duration value to as close as possible to the configurable delay value. The mitigation duration value may be adjusted to improve efficiency and/or performance of the response, e.g., by increasing a duration during which activity proceeds according to the nominal clock source.

According to a further approach, there is provided a method of monitoring an electronic circuit voltage droop response; the method comprising: switching activity, in response to a voltage droop event, from a nominal clock source to a fallback clock source; and switching activity, in response to a voltage recovery event, from a fallback clock source to a nominal clock source; wherein a voltage recovery event comprises a predetermined duration according to a configurable delay value without a voltage droop; and measuring a fallback duration during which activity proceeds according to the fallback clock source.

By measuring a fallback duration, an entire duration required for a voltage recovery event to be registered after activity is switched to the fallback clock source is measured. In other words, a portion of a mitigation event that is variable in duration depending on PDN voltage is measured. During the fallback duration, the voltage droop response causes activity to proceed according to the non-preferential clock source. The fallback duration will necessarily include the configurable delay value which defines a duration which must elapse without a voltage droop to trigger a voltage recovery event. A minimum value of fallback duration is identical to the configurable delay value. Accordingly, any greater value of fallback duration may be used as an indicator of inefficiency of the response. The fallback duration may be measured for each mitigation event.

The method may further comprise calculating a delay loop value by dividing the fallback duration by the configurable delay value. The delay loop value may recontextualise the fallback duration into a multiplier of the configurable delay value. A minimum value of fallback duration is identical to the configurable delay value. Accordingly, recording the fallback duration in terms of the configurable delay value may provide meaningful insight into characteristics of the voltage droop response.

The method may further comprise plotting the delay loop value in a histogram. By plotting a histogram, a distribution of delay loop values may be visualised. In particular, where a delay loop value is obtained for each mitigation event, it may be possible to compare how fallback duration compares with the configurable delay value over a large number of mitigation events. From the histogram, a user may verify the operation of the response or circuit and identify any modifications to the configurable delay value that may be appropriate.

The method may further comprise modifying the predetermined duration by reconfiguring the configurable delay value. Modifying the predetermined duration may modify the switching by adjusting the fallback duration. Such modification may be based on the histogram. Adjusting the fallback duration may comprise reducing the fallback duration, for example reducing the fallback duration to as close as possible to the configurable delay value. The fallback duration may be adjusted to improve efficiency and/or performance of the response, e.g., by increasing a duration during which activity proceeds according to the nominal clock source.

According to a further approach, there is provided an electronic circuit configured to monitor voltage droop response of another electronic circuit; the electronic circuit providing: a nominal clock source; a fallback clock source; a configurable delay value and a fallback duration value; wherein, in response to a voltage droop event, the electronic circuit is switched from the nominal clock source to the fallback clock source; and wherein, in response to a voltage recovery event, the electronic circuit is switched from the fallback clock source to a nominal clock source; wherein a voltage recovery event comprises a predetermined duration according to the configurable delay value without a voltage droop; and wherein a duration during which activity proceeds according to the fallback clock source is recorded as the fallback duration value.

The fallback duration value may be stored in a register. Accordingly, the fallback duration value may be monitored, used in calculation or act as a trigger in further circuit verification and optimisation circuits.

A delay loop value may be calculated by dividing the fallback duration value by the configurable delay value. The delay loop value may be plotted in a histogram. Advantages of calculating the delay loop value and plotting the same in a histogram are discussed above.

The configurable delay value may be reconfigurable to modify the predetermined duration. Modifying the predetermined duration may modify switching by adjusting the fallback duration value. Such modification may be based on the histogram. The fallback duration value may be adjusted to improve efficiency and/or performance of the response, e.g., by increasing a duration during which activity proceeds according to the nominal clock source.

According to a further approach, there is provided a method of monitoring an electronic circuit voltage droop response; the method comprising: switching activity, in response to a voltage droop event, from a nominal clock source to a fallback clock source; and switching activity, in response to a voltage recovery event, from a fallback clock source to a nominal clock source; and measuring a number of instances of switching from a fallback clock source to a nominal clock source occurring during a voltage droop.

By measuring a number of instances of switching from a fallback clock source to a nominal clock source occurring during a voltage droop, a number of failed mitigation events may be recorded. In normal operation, a voltage recovery event must take place for activity to be switched from a fallback clock source to a nominal clock source. Accordingly, if such switching occurs during a voltage droop, the PDN voltage must have drooped during the transition, or the transition must have been initiated without a voltage recovery event. Indeed, the switching itself may have caused or contributed to the PDN voltage droop. In any case, a further mitigation event may be immediately triggered resulting in activity being switched to the fallback clock source.

By measuring these instances, it may be determined that a greater period of recovery must be observed before activity may be switched back to the nominal clock source in order to avoid such switching causing an immediate further voltage droop event.

A voltage recovery event may comprise a predetermined duration according to a configurable delay value without a voltage droop. The method may further comprise modifying the configurable delay value based on the measured value. For example, a high measured value may indicate that an increase in the configurable delay value may be desirable. The method may comprise increasing the configurable delay value in response to a measured value above a predetermined threshold. In a similar way, the method may comprise decreasing the configurable delay value in response to a measured value below a predetermined threshold. The method may modify the configurable delay value iteratively to optimise response characteristics.

According to a further approach, there is provided an electronic circuit configured to monitor voltage droop response of another electronic circuit; the electronic circuit providing: a nominal clock source; a fallback clock source; and an exit count value; wherein, in response to switching activity from the fallback clock source to the nominal clock source during a voltage droop, the exit count value is incremented.

The exit count value may be stored in a register. Accordingly, the exit count value may be monitored, used in calculation or act as a trigger in further circuit verification and optimisation circuits.

According to a further approach, there is provided a method of monitoring an electronic circuit voltage droop response; the method comprising two or more of the methods of approaches of the disclosure.

By monitoring an electronic circuit voltage droop response using more than one of the methods of this disclosure, an accurate view of characteristics of the response may be obtained. Further, modification of switching may achieve a voltage droop response that is more optimised. Furthermore, modification to achieve an optimised response may take place more quickly. For example, by monitoring both the mitigation count value and the mitigation duration value, the user or control system may balance reducing a number of mitigation events with reducing a duration of each event to modify switching to achieve an optimal voltage droop response. For example, it may be preferable to have a high number of mitigation events where each event is relatively short, than to have a low number of mitigation events where each event is relatively long. By combining methods of the disclosure, telemetry of the voltage droop response may be improved, and a preferential voltage droop response may be achieved.

According to a further approach, there is provided an electronic circuit configured to monitor voltage droop response of another electronic circuit; the electronic circuit comprising two or more of the electronic circuits of approaches of the disclosure. Advantages of such an approach are discussed above.

According to a further approach, there is provided a method of monitoring an electronic circuit voltage droop response; the method comprising: switching activity, in response to a voltage droop event, from a nominal clock source to a fallback clock source; switching activity, in response to a voltage recovery event, from a fallback clock source to a nominal clock source; wherein a voltage recovery event comprises a predetermined duration according to a configurable delay value without a voltage droop; measuring a number of instances of switching from a nominal clock source to a fallback clock source; measuring an actual duration during which activity proceeds according to the fallback clock source without a voltage droop; measuring a fallback duration during which activity proceeds according to the fallback clock source; measuring a number of instances of switching from a fallback clock source to a nominal clock source occurring during a voltage droop; and modifying the switching to optimise activity efficiency based on the measuring. Examples and advantages of such an approach are discussed above.

According to a further approach, there is provided an electronic circuit configured to monitor voltage droop response of another electronic circuit; the electronic circuit providing: a nominal clock source; a fallback clock source; a mitigation count value; a configurable delay value, a mitigation duration value; fallback duration value; and an exit count value; wherein, in response to a voltage droop event, the electronic circuit is switched from a nominal clock source to a fallback clock source; wherein, in response to a voltage recovery event, the electronic circuit is switched from the fallback clock source to a nominal clock source; wherein a voltage recovery event comprises a predetermined duration according to the configurable delay value without a voltage droop; wherein, in response to switching the electronic circuit from the nominal clock source to the fallback clock source, the mitigation count value is incremented; wherein a duration during which activity proceeds according to the fallback clock source without a voltage droop is recorded as the mitigation duration value; wherein a duration during which activity proceeds according to the fallback clock source is recorded as the fallback duration value; wherein, in response to switching activity from the fallback clock source to the nominal clock source during a voltage droop, the exit count value is incremented; and wherein, in response to the measured values, switching is modified to optimise electronic circuit efficiency. Examples and advantages of such an approach are discussed above.

Any method according to an approach of present techniques may further comprise adjusting, in response to measured data, at least one of: the configurable delay value; a droop voltage threshold; a recovery voltage threshold; and an energy storage capacity of a power delivery network to increase a duration during which activity proceeds according to the nominal clock source.

In any electronic circuit according to an approach of present techniques, in response to measured data, at least one of: the configurable delay value; a droop voltage threshold; a recovery voltage threshold; and an energy storage capacity of a power delivery network may be adjusted to increase a duration during which activity proceeds according to the nominal clock source.

The configurable delay value is discussed in detail with respect to preceding approaches.

As discussed above, the droop voltage threshold may be a voltage level below which a voltage droop event is triggered. In other words, when the power delivery network voltage droops below the droop voltage threshold, a voltage droop event is triggered. The recovery voltage threshold may be a voltage level above which the voltage is considered recovered from a voltage droop event. In other words, when the power delivery network voltage recovers above the recovery voltage threshold, a voltage droop is no longer detected, and the mitigation duration counter may begin decrementing. In normal operation, the recovery voltage threshold must be exceeded before activity may be switched to the nominal clock to end the mitigation event.

By adjusting the droop voltage threshold and the recovery voltage threshold, switching may be adjusted. For example, reducing the value of the droop voltage threshold may cause fewer voltage droop events to be triggered. Similarly, reducing the value of the recovery voltage threshold may result in a reduced duration of a mitigation event.

Adjusting the energy storage capacity of a power delivery network may comprise adjusting a capacitance and/or an inductance of the power delivery network. Additionally or alternatively, adjusting the energy storage capacity of a power delivery network may comprise switching a power source from a first power delivery network configuration to a second power delivery network configuration.

The adjusting in response to measured data discussed above may increase a duration during which activity proceeds according to the nominal clock source. Simultaneously, this may decrease a duration during which activity proceeds according to the fallback clock source or the zero source. As a result of such adjustment, there may be fewer mitigation events. Additionally or alternatively, mitigation events may have reduced duration. In this way, the method or electronic circuit may be more efficient while adequately mitigating voltage droop. For example, by maximising a proportion of a duration during which the PDN is delivering a nominal voltage that is spent operating according to the nominal clock source, while mitigating negative effects of PDN voltage droop by reducing a frequency of the output clock by switching it to a fallback clock source when necessary, a circuit may operate efficiently.

According to a further approach, there is provided an electronic circuit comprising electronic logic components operable to perform the steps of the method of any approach of the disclosure.

According to a further approach, there is provided a non-transitory computer-readable medium to store computer-readable code for fabrication of an electronic circuit according to any approach of the disclosure.

According to a further approach, there is provided a system comprising: the electronic circuit of any approach of the disclosure implemented in at least one packaged chip; at least one system component; and a board; wherein the at least one packaged chip and the at least one system component are assembled on the board.

According to a further approach, there is provided a chip-containing product comprising the system of an approach of the disclosure assembled on a further board with at least one other product component.

According to a further approach, there is provided a non-transitory computer-readable medium to store computer-readable code for fabrication of the circuitry for monitoring an electronic circuit voltage droop response of any preceding approach of the disclosure.

### BRIEF DESCRIPTION OF THE DRAWINGS

Implementations of the disclosed technology will now be described, by way of example only, with reference to the accompanying drawings, in which:

FIG. 1 shows a flow diagram for switching from a nominal clock source to a fallback clock source comprising the telemetry of the disclosure;

FIG. 2 shows a flow diagram according to FIG. 1 with minimal transition pause;

FIG. 3 shows a flow diagram according to FIG. 1 without switching to a fallback clock source;

FIG. 4 shows a system and a chip-containing product; and

FIG. 5 shows a simple example of a multiplex arrangement operable to implement at least a part of the process of the present technology in hardware.

### DETAILED DESCRIPTION

Switching activity of synchronous digital circuits on a chip, such as circuits implementing processors, can vary significantly over a small number of clock cycles (typically <10). This may correspond to periods shorter than response times of power supplies and a power distribution network (PDN) to the chip, which may result in transient variations of a supply voltage. Voltage droops are of particular concern, as a reduction in voltage may cause the digital circuit to execute incorrectly (e.g., brown-out). Operating at excess voltage to mitigate such brown-out events during a rare voltage droop is undesirable as it increases a power consumption of the digital circuit.

The methods described herein refer to reactive droop mitigation schemes with low intervention latency. These techniques rely on dedicated circuitry to protect the operation of a digital circuit, a subject circuit. This includes the detection of one or more types of voltage droop conditions and application of a mitigation response to the synchronous clock that drives the activity of the subject circuit. Present techniques discuss monitoring the mitigation action taken in response to a voltage droop in an electronic circuit (e.g., a droop detector circuit), for example, to measure and improve efficiency of the mitigation action.

Clock management of Central Processing Unit (CPU) and Graphics Processing Unit (GPU) shader cores has a direct impact on system performance especially in thermally constrained environments for battery operated devices.

Modern day CPUs and GPUs experience voltage droops due to large changes in current required from the Power Delivery Network (PDN). This calls for mitigation techniques to minimise voltage margining to reduce power required and heat generated, whilst minimising any effect on performance. Lowering the clock frequency during a droop event is one such mitigation strategy.

Sustaining performance during a voltage droop event requires a robust mechanism to reduce heat generation. Lowering clock frequency is one of the techniques used to manage the thermal budget and extend battery life.

An electronic circuit may comprise a nominal clock source and a fallback clock source. An output clock may proceed according to either of the nominal clock source and a fallback clock source according to a clock selection variable, clk_sel. The nominal clock may run at a nominal frequency, the fallback clock may run at fallback frequency that is less than the nominal frequency. It is desirable to increase a performance and efficiency by maximising a duration during which the output clock proceeds according to the nominal clock, i.e., at the nominal, higher, frequency. However, this may only be appropriate when the PDN is delivering a nominal voltage. When heavily loaded, the voltage from the PDN may droop. Negative effects of PDN voltage droop such as performance reduction, increased heat generation and reduced battery life may be mitigated by reducing a frequency of the output clock, by switching it to a fallback clock source.

Power Delivery Network characteristics vary over silicon on chip systems. Accordingly, a standardised droop response is not appropriate for every PDN implementation. Present techniques provide a way of monitoring or verifying a voltage droop response, depending on system characteristics. In one example, a user tests the power delivery system, evaluates a droop response using the present monitoring techniques and adjusts the droop response based on telemetry data provided by the present monitoring techniques indicative of the Power Delivery Network characteristics. In another example, the present techniques include monitoring the power delivery system during operation and adjusting the droop response to optimise performance, for example, iteratively adjusting parameters of the droop response function to minimise droop mitigation events or droop mitigation duration.

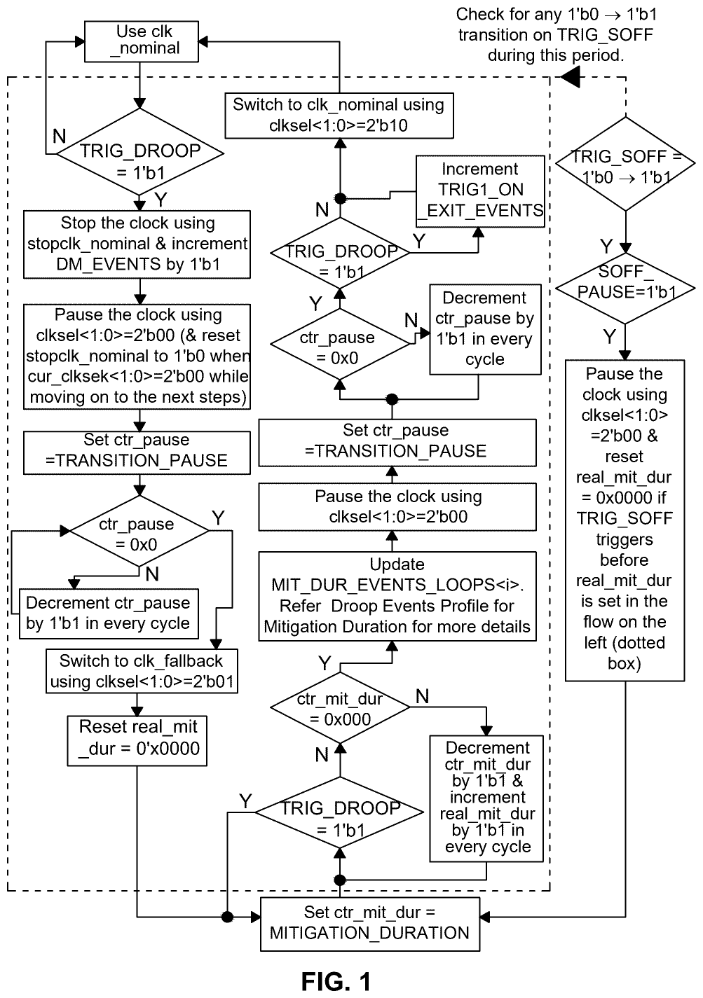

FIG. 1 shows a flow diagram for switching from a nominal clock source to a fallback clock source comprising the telemetry of the present techniques. When a voltage droop event is detected, TRIG_DROOP is set to 1′b1 and a mitigation event is triggered. A mitigation event comprises switching activity from the nominal clock source to an alternative clock source, and switching activity back to the nominal clock source in response to a voltage recovery event. A number of instances of switching activity from the nominal clock source to an alternative clock source is measured by incrementing a mitigation count value, DM_EVENTS, by 1′b1 in response to said switching.

After DM_EVENTS is incremented by 1′b1, a clock selection variable, clk_sel, is set to zero, 2′b00, pausing activity. After the elapse of a configurable transition pause, TRANSITION_PAUSE, activity is switched to the fallback clock source by setting clk_sel to 2′b01. At this point, variable real_mit_dur, used to measure the actual duration during which activity proceeds according to the fallback clock source without a voltage droop, is reset to zero. A mitigation duration counter, ctr_mit_dur is set to the configurable MITIGATION_DURATION and TRIG_DROOP is polled to detect a recovery in voltage such that a voltage is no longer drooped.

When such a recovery is detected, the mitigation duration counter begins decrementing and real_mit_dur begins incrementing while a voltage droop is absent. A voltage recovery event occurs when the mitigation duration counter reaches zero. As a result, activity is switched from the fallback clock source to the nominal clock source. Accordingly, a minimum value reached by real_mit_dur during a mitigation event is the value of MITIGATION_DURATION. In the alternative, if voltage droops again, TRIG_DROOP going high to 1′b1, before the mitigation duration counter reaches zero, ctr_mit_dur is reset to MITIGATION_DURATION.

If the mitigation duration counter reaches zero, the value of real_mit_dur, the actual duration during which activity proceeds according to the fallback clock source without a voltage droop, is recorded by incrementing a loop count value, MIT_DUR_EVENTS_LOOPS<i>, where i is a delay loop value, calculated by dividing the actual duration, real_mit_dur, by the configurable delay value, MITIGATION_DURATION and rounding down to the nearest integer. In an alternate implementation, the ceiling or floor of the quotient of dividing real_mit_dur by MITIGATION_DURATION can be taken. If the calculated delay loop value exceeds 4, the delay loop value is set to 4. In this way, the delay loop value is a value of the actual duration in terms of the minimum duration. Any suitable delay loop value, i, may be used to provide any suitable number of MIT_DUR_EVENTS_LOOPS<i> values. For example, i may be any integer between 3 and 10, or may be an integer greater than 10.

Loop count values MIT_DUR_EVENTS_LOOPS<i>, where i is an integer and 1≤i≤4, may be used to visualise characteristics of the voltage droop response. The minimum value of the delay loop value, i, is 1 because real_mit_dur increments all the while that the mitigation duration counter decrements from MITIGATION_DURATION to zero without a voltage droop.

When the mitigation duration counter reaches zero, activity is switched from the fallback clock source to the nominal clock source. The clock selection variable, clk_sel, is set to zero, 2′b00, pausing activity. After the elapse of the configurable transition pause, TRANSITION_PAUSE, if TRIG_DROOP is high, 1′b1, an exit count value, TRIG1_ON_EXIT_EVENTS, is incremented. Finally, activity is switched to the nominal clock source by setting clk_sel to 2′b10, and activity proceeds according to the nominal clock source.

Alternatively, the real_mit_dur counter may be incremented in each cycle. When a recovery in voltage such that a voltage is no longer drooped is detected, the mitigation duration counter begins decrementing. A voltage recovery event occurs when the mitigation duration counter reaches zero. As a result, activity is switched from the fallback clock source to the nominal clock source. In the alternative, if voltage droops again, TRIG_DROOP going high to 1′b1, before the mitigation duration counter reaches zero, ctr_mit_dur is reset to MITIGATION_DURATION, while the real_mit_dur counter keeps on incrementing in every clock cycle. In this way, an accurate measurement of the duration during which activity proceeds according to the fallback clock source is obtained.

The flowchart of FIG. 1 further shows a response of the voltage droop mitigation system to a sign off violation event occurring during droop mitigation (i.e. where the voltage drops too low). A sign off violation event may be a severe voltage droop event, an event for which switching to the fallback clock frequency is not sufficient to ensure correct execution of the circuit function. A sign off violation may be the result of a rare, deep droop event such as a brown-out from the power-source. Alternatively, when a circuit is operating at a lower bound of an acceptable voltage margin, any voltage droop may trigger a sign off violation, as any drop in voltage risks causing hold-timing failures as opposed to set-up timing failures which may be addressed by frequency reduction, i.e., switching to a fallback clock source.

If a sign off violation event is detected, TRIG_SOFF is set to 1′b1 and a sign off mitigation event is triggered. As a result, activity is paused, (switched to a zero source) i.e., no clock is selected by clk_sel, and real_mit_dur is reset to zero. Next, the mitigation duration counter, ctr_mit_dur is set to the MITIGATION_DURATION, and TRIG_DROOP is polled to detect a recovery in voltage such that a voltage is no longer drooped.

In some cases, while TRIG_SOFF is high, TRIG_DROOP is also high by default as both variables indicate a voltage droop, each with a predetermined voltage threshold trigger below a nominal voltage wherein the voltage threshold trigger for TRIG_SOFF is a lower voltage than the voltage threshold trigger for TRIG_DROOP. In other cases, TRIG_SOFF and TRIG_DROOP are mutually exclusive as each indicates a voltage droop into a predetermined range wherein the ranges have no overlap. In still further cases, TRIG_SOFF and TRIG_DROOP are not mutually exclusive as each indicates a voltage droop into a predetermined range wherein the ranges have some overlap.

Once voltage recovers such that TRIG_DROOP goes low, to 1′b0, the mitigation duration counter begins decrementing and real_mit_dur begins incrementing while a voltage droop is absent. Alternatively, the real_mit_dur counter may be incremented irrespective of the state of TRIG_DROOP to measure a duration of a sign off violation event. Switching activity from a zero source (paused state) to a nominal clock source occurs as described above with respect to switching activity from a fallback clock source to a nominal clock source. A voltage recovery event occurs when the mitigation duration counter reaches zero, next real_mit_dur is recorded in the appropriate one of MIT_DUR_EVENTS_LOOPS<i>, and activity is switched to the nominal clock source after the configurable transition pause has elapsed.

The values of TRANSITION_PAUSE and MITIGATION_DURATION characterise the voltage droop response. Adjusting these values may adjust the response. For example, adjusting TRANSITION_PAUSE may adjust the delay between activity proceeding according to the nominal clock and proceeding according to the fallback clock during a switching of activity, and vice versa. As such, the value of TRANSITION_PAUSE defines at least a portion of the duration during which activity is paused while switching clock source.

Additionally, for example, adjusting MITIGATION_DURATION may adjust the delay between a voltage recovering and initiation of switching from the fallback clock source to the nominal clock source. Accordingly, MITIGATION_DURATION defines the duration required to trigger a voltage recovery event.

The values of TRANSITION_PAUSE and MITIGATION_DURATION are configurable. In other words, TRANSITION_PAUSE and MITIGATION_DURATION may be programmable. A user may configure the values of TRANSITION_PAUSE and MITIGATION_DURATION. Additionally or alternatively, the methods of present techniques may comprise steps of configuring these values to optimise the voltage droop response.

In some cases, TRANSITION_PAUSE provides a delay to allow a recovering voltage to continue climbing before activity is switched to the nominal source, such that the switching does not itself trigger a further voltage droop. Similarly, TRANSITION_PAUSE may provide a delay to allow a drooping voltage an opportunity to stabilise during the delay before activity proceeds according to the fallback clock source. Delaying initiating switching back to the nominal clock source by MITIGATION_DURATION, ensures that the voltage has been recovering for a minimum amount of time before switching. In this way, a switch may not be triggered by a temporary voltage recovery blip that is not part of a sustained recovery trajectory. Where the delay according to TRANSITION_PAUSE is an unconditional pause, unaffected by PDN voltage level, the delay according to MITIGATION_DURATION is affected by PDN voltage level, only starting to count when TRIG_DROOP is low and resetting in response to further droops. Accordingly, the delay according to MITIGATION_DURATION is monitored using real_mit_dur while TRANSITION_PAUSE may be monitored separately or not at all. The two variables provide complementary but different response adjustment opportunities and, as such, may each be iteratively adjusted based on the measured values of the mitigation count value, the actual duration, the fallback duration value and the exit count value to optimise response efficiency.

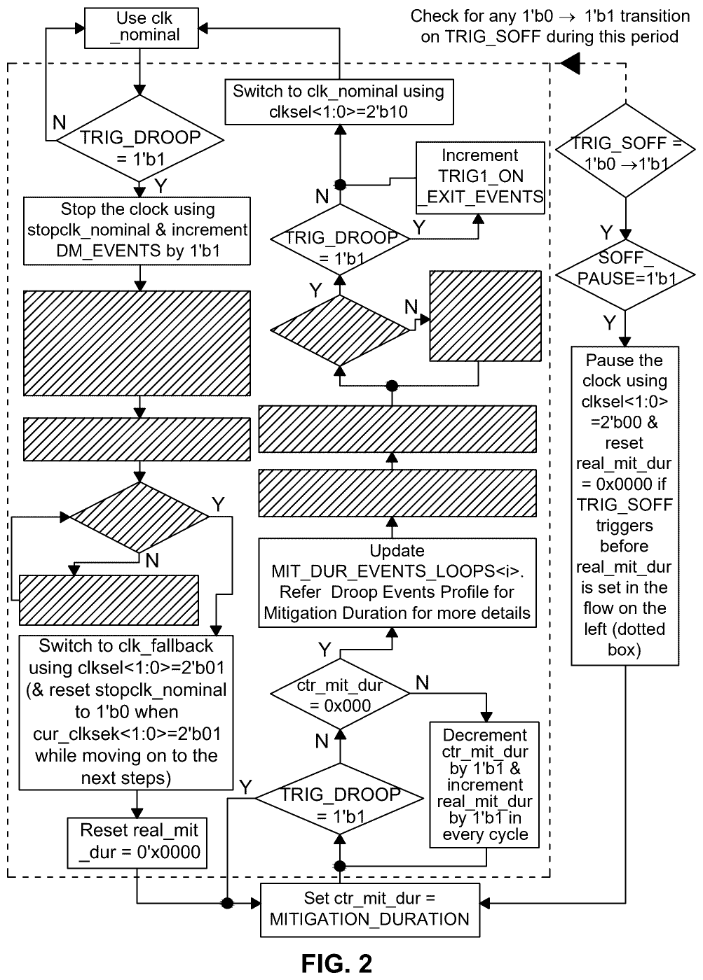

In some cases, the value of TRANSITION_PAUSE may be zero. For some Power Delivery Networks, the pause between switching the output clock from the nominal frequency to the fallback frequency should be minimised. In this case, as shown in FIG. 2, TRANSITION_PAUSE can be set to a minimum (zero) to minimise the pause and provide a direct transition from the nominal clock to the fallback clock (and back to the nominal clock) that is as fast as possible.

In some cases, it may be desirable to minimise MITIGATION_DURATION. For some Power Delivery Networks, particularly those suited to having a minimal pause between switching clock source, it may be advantageous to minimise the delay between a voltage recovering and initiation of switching, possibly even to zero.

With reference to FIG. 2, a flowchart showing the flow of FIG. 1 wherein TRANSITION_PAUSE is zero is shown. Note that the solid boxes are to be bypassed, they are shown to ease comparison across different mitigation flows. As such, there is no configurable delay during a transition from nominal clock source to fallback clock source or during a transition from fallback clock source to nominal clock source. According to such a flow, activity may switch directly from a nominal clock source to a fallback clock source, for example, clk_sel may switch directly from 2′b10 to 2′b01 without being set to 2′b00 at all. This is referred to as “Immediate Transition”. In this way, efficiency may be improved as a duration during which the output clock is paused may be minimised (e.g., may be zero).

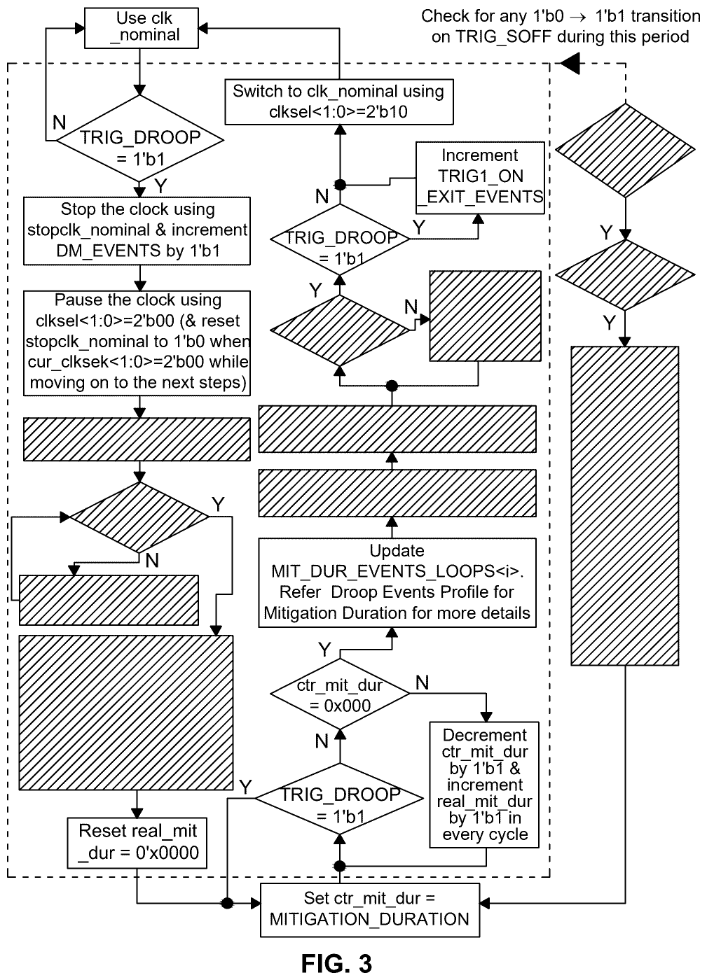

With reference to FIG. 3, a flowchart showing the flow of FIG. 1 wherein activity is stopped, or paused, for an entire mitigation event instead of being switched to a fallback clock source. According to such a flow, activity may switch directly from a nominal clock source to a zero source, for example, clk_sel may switch directly from 2′b10 to 2′b00. This is referred to as “Stop Clock on Droop”. Since the clock is stopped on droop, the value of TRANSITION_PAUSE has no significance. Further, the response to sign off violation events is the same as response to a droop event. Note that the solid boxes are to be bypassed, they are shown to ease comparison across different mitigation flows. This flow illustrates a streamlined approach wherein the output clock is stopped during the entire duration of a mitigation event in response to a voltage droop.

The method and circuit according to the present technology may thus be used in monitoring droop mitigation in systems having dynamic voltage and frequency scaling, and that method may be realised in the form of a non-transitory computer readable medium comprising a structure of data and imperatives operable to cause a device to construct a set of electronic logic components which, when embedded in an electronic device and activated thereon, cause the electronic device to perform the steps of the method of the present technology as described hereinabove.

As will be clear to one of skill in the art, a hybrid approach may also be taken, in which hardware logic, firmware and/or software may be used in any combination to implement the present technology.

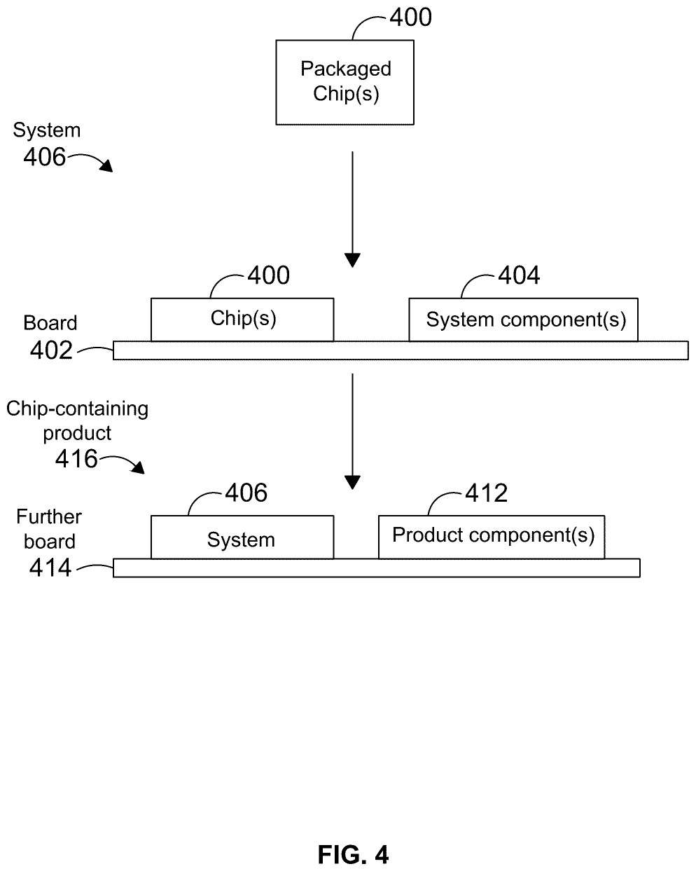

As shown in FIG. 4, one or more packaged chips 400, with the circuitry described above implemented on one chip or distributed over two or more of the chips, are manufactured by a semiconductor chip manufacturer. In some examples, the chip product 400 made by the semiconductor chip manufacturer may be provided as a semiconductor package which comprises a protective casing (e.g., made of metal, plastic, glass or ceramic) containing the semiconductor devices implementing the circuitry described above and connectors, such as lands, balls or pins, for connecting the semiconductor devices to an external environment. Where more than one chip 400 is provided, these could be provided as separate integrated circuits (provided as separate packages) or could be packaged by the semiconductor provider into a multi-chip semiconductor package (e.g., using an interposer, or by using three-dimensional integration to provide a multi-layer chip product comprising two or more vertically stacked integrated circuit layers).

In some examples, a collection of chiplets (i.e., small modular chips with particular functionality) may itself be referred to as a chip. A chiplet may be packaged individually in a semiconductor package and/or together with other chiplets into a multi-chiplet semiconductor package (e.g., using an interposer, or by using three-dimensional integration to provide a multi-layer chiplet product comprising two or more vertically stacked integrated circuit layers).

The one or more packaged chips 400 are assembled on a board 402 together with at least one system component 404 to provide a system 406. For example, the board may comprise a printed circuit board. The board substrate may be made of any of a variety of materials, e.g., plastic, glass, ceramic, or a flexible substrate material such as paper, plastic or textile material. The at least one system component 404 comprise one or more external components which are not part of the one or more packaged chip(s) 400. For example, the at least one system component 404 could include, for example, any one or more of the following: another packaged chip (e.g., provided by a different manufacturer or produced on a different process node), an interface module, a resistor, a capacitor, an inductor, a transformer, a diode, a transistor and/or a sensor.

A chip-containing product 416 is manufactured comprising the system 406 (including the board 402, the one or more chips 400 and the at least one system component 404) and one or more product components 412. The product components 412 comprise one or more further components which are not part of the system 406. As a non-exhaustive list of examples, the one or more product components 412 could include a user input/output device such as a keypad, touch screen, microphone, loudspeaker, display screen, haptic device, etc.; a wireless communication transmitter/receiver; a sensor; an actuator for actuating mechanical motion; a thermal control device; a further packaged chip; an interface module; a resistor; a capacitor; an inductor; a transformer; a diode; and/or a transistor. The system 406 and one or more product components 412 may be assembled on to a further board 414.

The board 402 or the further board 414 may be provided on or within a device housing or other structural support (e.g., a frame or blade) to provide a product which can be handled by a user and/or is intended for operational use by a person or company.

The system 406 or the chip-containing product 416 may be at least one of: an end-user product, a machine, a medical device, a computing or telecommunications infrastructure product, or an automation control system. For example, as a non-exhaustive list of examples, the chip-containing product could be any of the following: a telecommunications device, a mobile phone, a tablet, a laptop, a computer, a server (e.g. a rack server or blade server), an infrastructure device, networking equipment, a vehicle or other automotive product, industrial machinery, consumer device, smart card, credit card, smart glasses, avionics device, robotics device, camera, television, smart television, DVD players, set top box, wearable device, domestic appliance, smart meter, medical device, heating/lighting control device, sensor, and/or a control system for controlling public infrastructure equipment such as smart motorway or traffic lights.

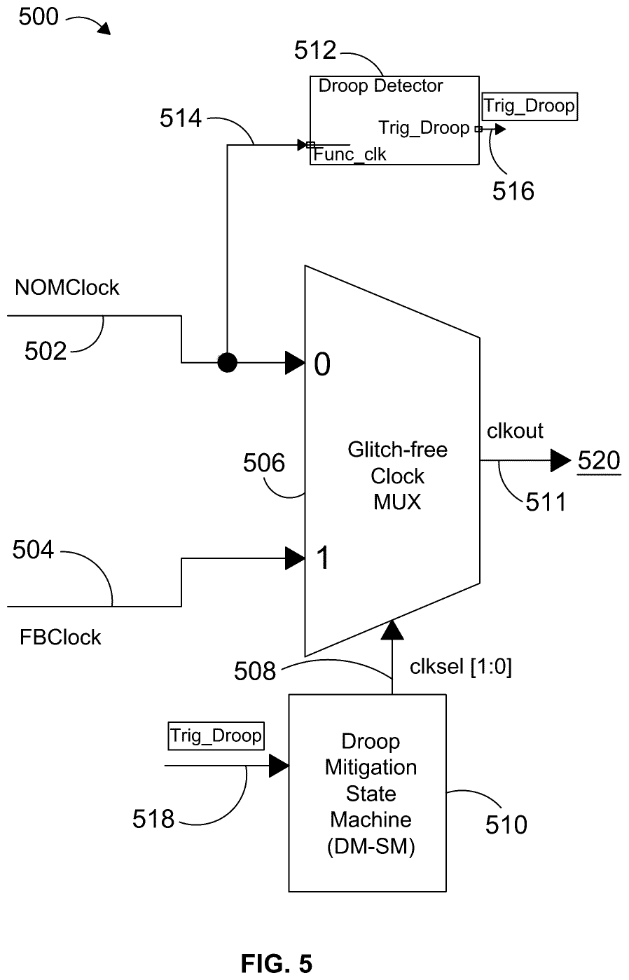

Referring to FIG. 5, a multiplexer structure operable to implement at least a part of the process of the present technology is shown in hardware. FIG. 5 shows a multiplexer 500 such as one module of part of a Clock Control State Machine (CCSM) arrangement operable in an electronic circuit.

There are several clock domains in a state machine according to present techniques. The output clock goes into two stages of clock mux. The first stage has a pair of clock muxes, which are controlled by clksel_nom and clksel_fb. The output of the first mux is called clk_nominal. This clock has the higher frequency and is typically a high frequency fast clock that goes into any CPU/GPU sub-system. The output of the second mux is called clk_fallback. This clock has the lower frequency and acts as a fallback frequency in case of a droop event. This is the fallback clock that goes into the CPU/GPU sub-system in the case of a droop event.

The second stage of clock mux, mux 506 shown in FIG. 5, is between clk_nominal 502 and clk_fallback 504. This is controlled by clksel 508. The control switches at the time of a droop event. The output of the mux is called clkout 511 and may correspond to a droop mitigated clock signal. In normal circumstances, clkout 511 is clk_nominal 502. Clkout 511 switches to clk_fallback 504 in case of a droop event. A droop event is detected by droop detector 512 which outputs a trigger signal 516, configured to trigger mitigation of the droop event, when provided to the droop mitigation state machine 510 via input 518. The droop mitigation state machine 510 outputs clk_sel 508 to adjust the mux 506 and thereby clkout 511 (the droop mitigated clock) accordingly.

Glitch-free clock mux 506 is operable to receive inputs NOM clock 502, representing the nominal clock source at the current normal voltage and frequency tuning, and FB clock 504, representing the currently available fallback clock source at the droop mitigation voltage and frequency. Clock mux 506 is controlled by clksel 508 to select the source to be used to provide output clkout 511.

Droop mitigation state machine 510 outputs clksel 508 in response to a detection of a droop event by droop detector 512 which has input func_clk 514 connected to NOM clock 502. Droop detector 512 has output TRIG_DROOP 516 connected to input 518 of droop mitigation state machine 510.

FIG. 5 thus shows an implementation of a glitch-free clock multiplexer that can have the following droop mitigation strategies for clkout 511 when TRIG_DROOP 516 is output:
Select the NOM clock if clksel[1:0]=2′b01. The droop event is ignored and the clksel is driven by clk_nominal.
Select the FB clock if clksel[1:0]=2′b10. The droop event caused clksel to switch to fallback frequency.
Select no clock if clksel[1:0]=0′b00. In other words, stop the clock propagation. This may be referred to as switching to a zero source.

As shown in FIG. 5, clkout 511 is the output of the clock multiplexer 506. The clock multiplexer 506 provides clkout 511 as a clock source to a subject circuit 520. The clock source may be mitigated to accommodate voltage droop. Accordingly, it is the subject circuit 520 that is protected from adverse effects of voltage droop, e.g., brown out, by the droop mitigation system. The nominal clock and fallback clock sources 502, 504 are inputs to the clock mux 506. The nominal clock source 502, also called the functional clock source 514, is also an input to the droop detector 512. In use, the droop mitigation state machine 510 controls which, if any, of the input clocks are propagated through the mux 506 to the clkout 511.

The monitoring according to present techniques may include monitoring a number of instances of switching controlled by the droop mitigation state machine 510. The monitoring of present techniques may also include monitoring a number of clock cycles of the functional clock 514 during which certain conditions are true, e.g., during which activity of the subject circuit 520 proceeds according to the fallback clock source 504 according to the control of the droop mitigation state machine 510. Accordingly, the activity switched may be activity of the subject circuit 520. The switching may be performed by the droop mitigation state machine 510. The monitoring according to present techniques may include monitoring the response of the mitigated clock (clkout) and/or of the droop mitigation state machine 510 to voltage droop detected by the droop detector 512. In this way, an impact of voltage droop on the subject circuit 520 may be monitored and minimised.

As will be appreciated by one skilled in the art, the present technology may be embodied as a method, a circuit or a computer readable medium comprising data and imperatives to cause construction of a circuit. Accordingly, the present techniques may take the form of an entirely hardware embodiment, an entirely software embodiment, or an embodiment combining software, firmware and hardware. Where the word “component” is used, it will be understood by one of ordinary skill in the art to refer to any portion of any of the above embodiments.

Furthermore, the present techniques may take the form of a computer program product tangibly embodied in a non-transitory computer readable medium having computer readable program code embodied thereon. A computer readable medium may be, for example, but is not limited to, an electronic, magnetic, optical, electromagnetic, infrared, or semiconductor system, apparatus, or device, or any suitable combination of the foregoing.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define an HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and System Verilog or other behavioural representations of the concepts that can be interpreted by a computer to enable simulation, functional and/or formal verification, and testing of the concepts.

Additionally or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the present techniques. Alternatively or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the present techniques. Alternatively or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

The program code may execute entirely on the user's computer, partly on the user's computer and partly on a remote computer or entirely on the remote computer or server. In the latter scenario, the remote computer may be connected to the user's computer through any type of network. Code components may be embodied as procedures, methods or the like, and may comprise sub-components which may take the form of instructions or sequences of instructions at any of the levels of abstraction, from the direct machine instructions of a native instruction-set to high-level compiled or interpreted language constructs.

It will also be clear to one of skill in the art that all or part of a logical method according to embodiments of the present techniques may suitably be embodied in a logic apparatus comprising logic elements to perform the steps of the method, and that such logic elements may comprise components such as logic gates in, for example a programmable logic array or application-specific integrated circuit. Such a logic arrangement may further be embodied in enabling elements for temporarily or permanently establishing logic structures in such an array or circuit using, for example, a virtual hardware descriptor language, which may be stored using fixed carrier media.

In one alternative, an embodiment of the present techniques may be realized in the form of a computer implemented method of deploying a service comprising steps of deploying computer program code operable to, when deployed into a computer infrastructure or network and executed thereon, cause the computer system or network to perform all the steps of the method.

In a further alternative, an embodiment of the present technique may be realized in the form of a data carrier having functional data thereon, the functional data comprising functional computer data structures to, when loaded into a computer system or network and operated upon thereby, enable the computer system to perform all the steps of the method.

In the present application, the words “configured to . . . ” are used to mean that an element of an apparatus has a configuration able to carry out the defined operation. In this context, a “configuration” means an arrangement or manner of interconnection of hardware or software. For example, the apparatus may have dedicated hardware which provides the defined operation, or a processor or other processing device may be programmed to perform the function. “Configured to” does not imply that the apparatus element needs to be changed in any way in order to provide the defined operation.

In the present application, lists of features preceded with the phrase “at least one of” mean that any one or more of those features can be provided either individually or in combination. For example, “at least one of: [A], [B] and [C]” encompasses any of the following options: A alone (without B or C), B alone (without A or C), C alone (without A or B), A and B in combination (without C), A and C in combination (without B), B and C in combination (without A), or A, B and C in combination.

Although illustrative embodiments of the present techniques have been described in detail herein with reference to the accompanying drawings, it is to be understood that the present techniques is not limited to those precise embodiments, and that many improvements and modifications can be made to the foregoing exemplary embodiments without departing from the scope of the present disclosure.

1. A method of monitoring an electronic circuit voltage droop response; the method comprising:
switching activity, in response to a voltage droop event, from a nominal clock source to a fallback clock source; and
measuring a number of instances of said switching.

2. The method of claim 1, further comprising modifying the switching to optimise activity efficiency based on the measuring.

3. The method of claim 1, further comprising:
switching activity, in response to a sign off violation event, from a nominal clock source to a zero source; and
measuring a number of instances of said switching.

4. The method of claim 1, further comprising:
switching activity, in response to a voltage recovery event, from a fallback clock source to a nominal clock source;
wherein a voltage recovery event comprises a predetermined duration according to a configurable delay value; and
measuring an actual duration during which activity proceeds according to the fallback clock source without a voltage droop.

5. The method of claim 4, further comprising modifying the predetermined duration by reconfiguring the configurable delay value.

6. The method of claim 4, further comprising measuring a fallback duration during which activity proceeds according to the fallback clock source.

7. The method of claim 4, further comprising measuring a number of instances of switching from a fallback clock source to a nominal clock source occurring during a voltage droop.

8. The method of claim 4, further comprising adjusting, in response to measured data, at least one of:
the configurable delay value;
a droop voltage threshold;
a recovery voltage threshold; and
an energy storage capacity of a power delivery network to increase a duration during which activity proceeds according to the nominal clock a source.

9. An electronic circuit configured to monitor voltage droop response of another electronic circuit; the electronic circuit providing:
a nominal clock source; a fallback clock source; and a mitigation count value;
wherein, in response to a voltage droop event, the electronic circuit is switched from a nominal clock source to a fallback clock source; and
wherein, in response to switching the electronic circuit from the nominal clock source to the fallback clock source, the mitigation count value is incremented.

10. The electronic circuit of claim 9, wherein, in response to the mitigation count value, switching is modified to optimise electronic circuit efficiency.

11. The electronic circuit of claim 9, the electronic circuit further providing a zero source and a sign off count value;
wherein, in response to a sign off violation event, activity is switched from the nominal clock source to the zero source; and
wherein, in response to switching activity from the nominal clock source to the zero source, the sign off count value is incremented.

12. The electronic circuit of claim 9, the electronic circuit further providing a configurable delay value and a mitigation duration value;
wherein, in response to a voltage recovery event, the electronic circuit is switched from the fallback clock source to a nominal clock source;
wherein a voltage recovery event comprises a predetermined duration according to the configurable delay value; and
wherein a duration during which activity proceeds according to the fallback clock source without a voltage droop is recorded as the mitigation duration value.

13. The electronic circuit of claim 12, wherein the configurable delay value is reconfigurable to modify the predetermined duration.

14. The electronic circuit of claim 12, the electronic circuit further providing a fallback duration value;
wherein a duration during which activity proceeds according to the fallback clock source is recorded as the fallback duration value.

15. The electronic circuit of claim 12, the electronic circuit further providing an exit count value;
wherein, in response to switching activity from the fallback clock source to the nominal clock source during a voltage droop, the exit count value is incremented.

16. A non-transitory computer-readable medium to store computer-readable code for fabrication of the electronic circuit according of claim 9.

17. A system comprising:
the electronic circuit of claim 9 implemented in at least one packaged chip;
at least one system component; and
a board;
wherein the at least one packaged chip and the at least one system component are assembled on the board.

18. A chip-containing product comprising the system of claim 17 assembled on a further board with at least one other product component.

19. An electronic circuit configured to monitor voltage droop response of another electronic circuit; the electronic circuit providing:
a nominal clock source; a fallback clock source; a configurable delay value and a mitigation duration value;
wherein, in response to a voltage droop event, the electronic circuit is switched from the nominal clock source to the fallback clock source; and
wherein, in response to a voltage recovery event, the electronic circuit is switched from the fallback clock source to a nominal clock source;
wherein a voltage recovery event comprises a predetermined duration according to the configurable delay value; and
wherein a duration during which activity proceeds according to the fallback clock source without a voltage droop is recorded as the mitigation duration value.

20. The electronic circuit of claim 19, wherein, in response to the mitigation count value, switching is modified to optimise electronic circuit efficiency.
